(19) United States
(12) Patent Application Publication
(10) Pub. No.: US 2013/0033335 A1
(43) Pub. Date: Feb. 7, 2013

(54) SYSTEM AND METHOD FOR TUNING A SEMI-DIGITAL FINITE IMPULSE RESPONSE (sFIR) FILTER

(71) Applicants: John W. Simmons, Tamarac, FL (US); Kristopher K. Kaufman, Gilbert, AZ (US); Michael L. Gomez, Tempe, AZ (US)

(72) Inventors: John W. Simmons, Tamarac, FL (US); Kristopher K. Kaufman, Gilbert, AZ (US); Michael L. Gomez, Tempe, AZ (US)

(73) Assignee: FUJITSU SEMICONDUCTOR LIMITED, Kanagawa (JP)

(21) Appl. No.: 13/195,486

(22) Filed: Aug. 1, 2011

(51) Int. Cl. H03B 5/18; G06G 7/02

(52) U.S. Cl. 331/177 V; 708/819

(57) ABSTRACT

In accordance with some embodiments of the present disclosure, a method for tuning a semi-digital finite impulse response (sFIR) filter comprises coupling a switch between an output of a shift register element associated with an input of the sFIR filter and a resistor coupled to an output of the sFIR filter. The shift register element and the resistor are associated with a tap of the sFIR filter. The method further comprising at least one of closing the switch according to a control signal to couple the resistor with the output of the shift register element such that a tap is added to the sFIR filter and opening the switch according to the control signal to decouple the resistor from the output of the shift register element such that a tap is subtracted from the sFIR filter to tune the corner frequency of the sFIR filter.

### TECHNICAL FIELD

The present disclosure relates generally to semi-digital finite impulse response (sFIR) filters, including, without limitation, a system and method for tuning a semi-digital finite impulse response filter.

### BACKGROUND

Wireless communications systems are used in a variety of telecommunications systems, television, radio and other media systems, data communication networks, and other systems to convey information between remote points using wireless transmitters and wireless receivers. A transmitter is an electronic device which, usually with the aid of an antenna, propagates an electromagnetic signal such as radio, television, or other telecommunications. Transmitters often include signal amplifiers which receive a radio-frequency or other signal, amplify the signal by a predetermined gain, and communicate the amplified signal. A receiver is an electronic device which receives and processes a wireless electromagnetic signal. A transmitter and receiver may be combined into a single device called a transceiver.

Transmitters, receivers, and transceivers often include components known as oscillators. An oscillator may serve many functions in a transmitter, receiver, and/or transceiver, including generating a local oscillator signal (e.g., a clock signal) (usually in a radio-frequency range) for upconverting baseband signals onto a radio-frequency (RF) carrier and performing modulation for transmission of signals, and/or for downconverting RF signals to baseband signals and performing demodulation of received signals.

Some oscillators may comprise a voltage controlled oscillator module configured to generate the clock signal, where the frequency of the oscillator may be controlled by a control voltage. The control voltage may be based on a control signal from a digital controller and the control signal may be converted into an analog signal by a digital to analog converter (DAC). However, the DAC may have undesirable high frequency, high power noise. Traditional systems may use a passive resistor/capacitor (RC) network to filter out this noise. However, such networks may not be sufficiently precise, especially considering variations that may occur during fabrication.

### SUMMARY

In accordance with some embodiments of the present disclosure, a method for tuning a semi-digital finite impulse response (sFIR) filter comprises coupling a switch between an output of a shift register element associated with an input of the sFIR filter and a resistor coupled to an output of the sFIR filter. The shift register element and the resistor are associated with a tap of the sFIR filter. The method further comprising at least one of closing the switch according to a control signal to couple the resistor with the output of the shift register element such that a tap is added to the sFIR filter in order to tune a corner frequency of the sFIR filter and opening the switch according to the control signal to decouple the resistor from the output of the shift register element such that a tap is subtracted from the sFIR filter in order to tune the corner frequency of the sFIR filter.

### BRIEF DESCRIPTION OF THE DRAWINGS

For a more complete understanding of the present disclosure and its features and advantages, reference is now made to the following description, taken in conjunction with the accompanying drawings, in which:

FIG. 1 illustrates a block diagram of an example wireless communication system, in accordance with certain embodiments of the present disclosure;

FIG. 2 illustrates a block diagram of selected components of an example transmitting and/or receiving element, in accordance with certain embodiments of the present disclosure; and

FIG. 3 illustrates an example of an oscillator circuit with a tunable semi-digital finite impulse response (sFIR) filter, in accordance with certain embodiments of the present disclosure.

### DETAILED DESCRIPTION

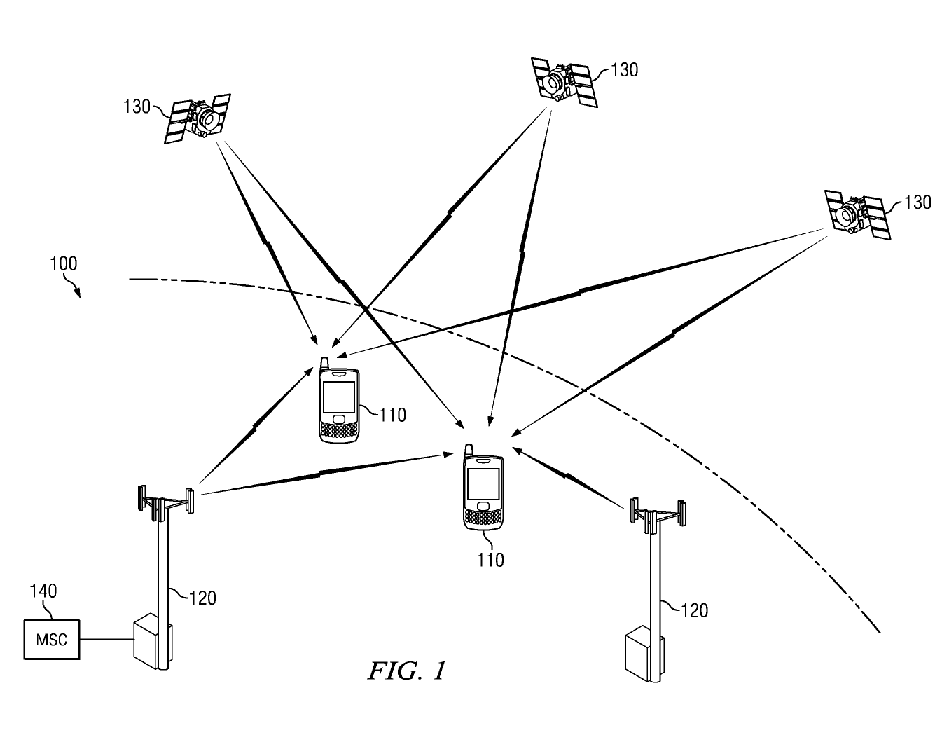

FIG. 1 illustrates a block diagram of an example wireless communication system 100, in accordance with certain embodiments of the present disclosure. For simplicity, only two terminals 110 and two base stations 120 are shown in FIG. 1. A terminal 110 may also be referred to as a remote station, a mobile station, an access terminal, user equipment (UE), a wireless communication device, a cellular phone, or some other terminology. A base station 120 may be a fixed station and may also be referred to as an access point, a Node B, or some other terminology. A mobile switching center (MSC) 140 may be coupled to the base stations 120 and may provide coordination and control for base stations 120.

A terminal 110 may or may not be capable of receiving signals from satellites 130. Satellites 130 may belong to a satellite positioning system such as the well-known Global Positioning System (GPS). Each GPS satellite may transmit a GPS signal encoded with information that allows GPS receivers on earth to measure the time of arrival of the GPS signal. Measurements for a sufficient number of GPS satellites may be used to accurately estimate a three-dimensional position of a GPS receiver. A terminal 110 may also be capable of receiving signals from other types of transmitting sources such as a Bluetooth transmitter, a Wireless Fidelity (Wi-Fi) transmitter, a wireless local area network (WLAN) transmitter, an IEEE 802.11 transmitter, and any other suitable transmitter.

In FIG. 1, each terminal 110 is shown as receiving signals from multiple transmitting sources simultaneously, where a transmitting source may be a base station 120 or a satellite 130. In certain embodiments, a terminal 110 may also be a transmitting source. In general, a terminal 110 may receive signals from zero, one, or multiple transmitting sources at any given moment.

System 100 may be a Code Division Multiple Access (CDMA) system, a Time Division Multiple Access (TDMA) system, or some other wireless communication system. A CDMA system may implement one or more CDMA standards such as IS-95, IS-2000 (also commonly known as “1x”), IS-856 (also commonly known as “1xEV-DO”), Wideband-CDMA (W-CDMA), and so on. A TDMA system may implement one or more TDMA standards such as Global System for Mobile Communications (GSM). The W-CDMA standard is defined by a consortium known as 3GPP, and the IS-2000 and IS-856 standards are defined by a consortium known as 3GPP2.

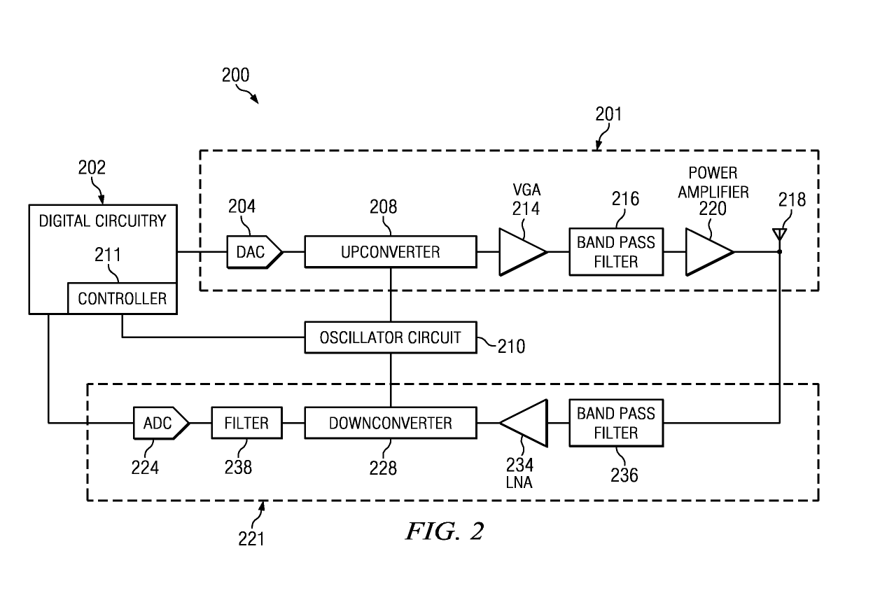

FIG. 2 illustrates a block diagram of selected components of an example transmitting and/or receiving element 200 (e.g., a terminal 110, a base station 120, or a satellite 130), in accordance with certain embodiments of the present disclosure.

As discussed further below, element 200 may include an oscillator circuit 210 that may comprise a voltage controlled oscillator module configured to generate a clock signal, where the frequency of the oscillator may be controlled by a control voltage. The control voltage may be based on a control signal from digital circuitry 202 and the control signal may be converted into an analog signal by a digital to analog converter (DAC) of oscillator circuit 210. As described in further detail below, oscillator circuit 210 may also include a tunable, semi-digital finite impulse response (sFIR) filter configured to filter out noise that may be generated by the DAC controlling the oscillator circuit. The sFIR filter may include both digital and analog components that may filter generated by the DAC. As such, the sFIR filter may include a digital corner frequency and an analog corner frequency. As discussed further below, the sFIR filter may be configured to be tuned such that its analog corner frequency may more closely relate to a desired analog corner frequency to more effectively filter out the noise of the DAC.

Element 200 may include a transmit path 201 and/or a receive path 221. Depending on the functionality of element 200, element 200 may be considered a transmitter, a receiver, or a transceiver.

As depicted in FIG. 2, element 200 may include digital circuitry 202. Digital circuitry 202 may include any system, device, or apparatus configured to process digital signals and information received via receive path 221, and/or configured to process signals and information for transmission via transmit path 201. Such digital circuitry 202 may include one or more microprocessors, digital signal processors, and/or other suitable devices. In the present embodiment, digital circuitry 202 may include a controller 211. Controller 211 may be configured to generate a control signal to dictate the frequency of oscillator circuit 210. As discussed above, the control signal may be converted into a control voltage by a DAC of oscillator circuit 210. Further, as described below, controller 211 may be configured to generate a tuning signal configured to tune the tunable sFIR filter of oscillator circuit 210.

Controller 211 may comprise any system, device, or apparatus configured to interpret and/or execute program instructions and/or process data, and may include without limitation a microprocessor, microcontroller, digital signal processor (DSP), application specific integrated circuit (ASIC), or any other digital or analog circuitry configured to interpret and/or execute program instructions and/or process data. In some embodiments, controller 211 may interpret and/or execute program instructions and/or process data stored in memory communicatively coupled to controller 211 (not expressly shown).

Memory may comprise any system, device or apparatus operable to retain program instructions or data for a period of time (e.g., computer-readable media). Memory may include random access memory (RAM), electrically erasable programmable read-only memory (EEPROM), a PCMCIA card, flash memory, magnetic storage, opto-magnetic storage, or any suitable selection and/or array of volatile or non-volatile memory that retains data after power to controller 211 is turned off.

Transmit path 201 may include a digital-to-analog converter (DAC) 204. DAC 204 may be configured to receive a digital signal from digital circuitry 202 and convert such digital signal into an analog signal. Such analog signal may then be passed to one or more other components of transmit path 201, including upconverter 208. Upconverter 208 may be configured to frequency upconvert an analog signal received from DAC 204 to a wireless communication signal at a radio frequency based on an oscillator signal provided by oscillator circuit 210.

Oscillator circuit 210 may be any suitable device, system, or apparatus configured to produce an analog waveform of a particular frequency for modulation or upconversion of an analog signal to a wireless communication signal, or for demodulation or downconversion of a wireless communication signal to an analog signal. Accordingly, oscillator circuit 210 may produce a clock signal that may be used for modulation or demodulation.

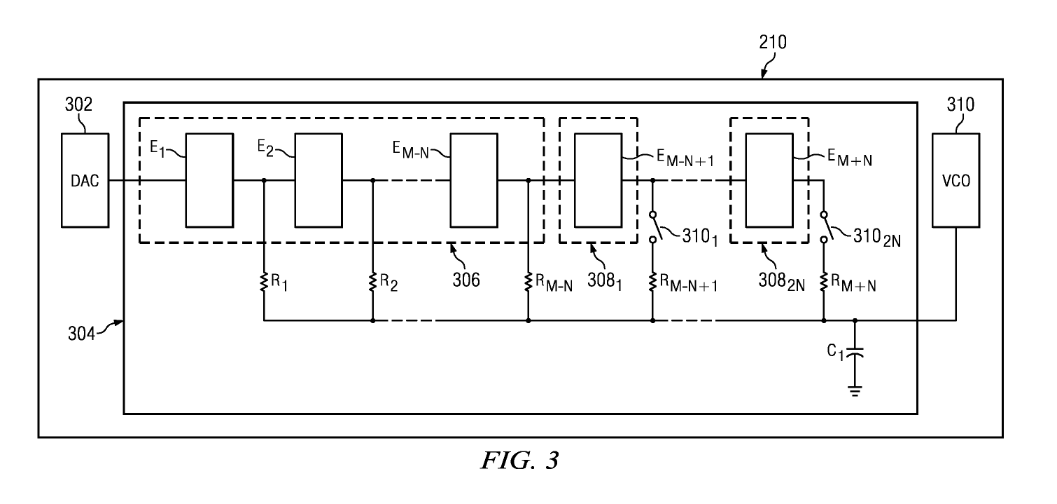

As described above, in some embodiments, oscillator circuit 210 may comprise a voltage controlled oscillator module configured to generate a clock signal having the desired frequency according to a received control voltage that may be based on a control signal received from controller 211. As mentioned previously, and described in further detail with respect to FIG. 3, the control signal may be received by a DAC of oscillator circuit 210 and may be converted from a digital control signal into an analog control voltage by the DAC. Oscillator circuit 210 may also include a tunable sFIR filter coupled between the voltage controlled oscillator module and the DAC, and configured to filter out high power and high frequency noise generated by the DAC. Additionally, the tunable sFIR filter may be configured such that its analog corner frequency may be tuned to account for variations that may occur during fabrication. Accordingly, oscillator circuit 210 may produce a more accurate clock signal.

Transmit path 201 may include a variable-gain amplifier (VGA) 214 to amplify an upconverted signal for transmission, and a bandpass filter 216 configured to receive an amplified signal VGA 214 and pass signal components in the band of interest, and remove out-of-band noise and undesired signals. The bandpass filtered signal may be received by power amplifier 220 where it is amplified for transmission via antenna 218. Antenna 218 may receive the amplified signal from power amplifier 220 and may transmit the amplified signal through a wireless communication network (e.g., to one or more of a terminal 110, a base station 120, and/or a satellite 130).

Receive path 221 may include a bandpass filter 236 configured to receive a wireless communication signal (e.g., from a terminal 110, a base station 120, and/or a satellite 130) via antenna 218. Bandpass filter 236 may pass signal components in the band of interest and remove out-of-band noise and undesired signals. In addition, receive path 221 may include a low-noise amplifier (LNA) 224 to amplify a signal received from bandpass filter 236.

Receive path 221 may also include a downconverter 228. Downconverter 228 may be configured to frequency downconvert a wireless communication signal received via antenna 218 and amplified by LNA 234 by an oscillator signal provided by oscillator 210 (e.g., downconvert to a baseband signal). Receive path 221 may further include a filter 238, which may be configured to filter a downconverted wireless communication signal in order to pass the signal components within a radio-frequency channel of interest and/or to remove noise and undesired signals that may be generated by the downconversion process. In addition, receive path 221 may include an analog-to-digital converter (ADC) 224 configured to receive an analog signal from filter 238 and convert such analog signal into a digital signal. Such digital signal may then be passed to digital circuitry 202 for processing.

FIG. 3 illustrates an example of oscillator circuit 210 in accordance with certain embodiments of the present disclosure. Oscillator circuit 210 may include a DAC 302 configured to receive a control signal from a controller (e.g., controller 211 of FIG. 2). As mentioned above, the control signal may comprise a digital signal configured to control the frequency of a signal (e.g., a clock signal) generated by oscillator circuit 210. DAC 302 may be configured to convert the digital control signal into a control voltage that may be received by a voltage controlled oscillator (VCO) module 310 of oscillator circuit 210.

VCO module 310 may be configured to generate a signal having a particular frequency based on the received control voltage. A VCO may comprise any suitable component configured to generate a signal having a particular frequency according to a control voltage received by the VCO. In some embodiments, the VCO may comprise a voltage controlled, temperature compensated oscillator (VCTCXO) that may comprise any suitable component configured to generate a signal having a particular frequency according to a control voltage, and that also includes one or more temperature compensating components.

The control voltage generated by DAC 302 may include noise that may need to be filtered out such that VCO module 310 may generate a sufficiently clean signal. Accordingly, oscillator circuit 210 may also include a tunable sFIR filter 304 configured to have a digital corner frequency and an analog corner frequency at a desired level such that the noise of DAC 302 may be sufficiently filtered out. The output of sFIR filter 304 may be coupled to VCO module 310 such that VCO module 310 may receive the filtered signal.

As mentioned above, tunable sFIR filter 304 may be configured to have corner frequencies for filtering out noise that may be caused by DAC 302. Filter 304 may be configured such that the number of taps of filter 304 may be increased or decreased such that the analog component of filter 304 may be tuned to a desired corner frequency. Filter 304 may also include a capacitor C that may establish the analog corner frequency of filter 304. The desired analog corner frequency may be based on filtering out undesirable noise that may be generated by DAC 302.

Filter 304 may include a shift register 306 that may include “M-N” number of elements (e.g., elements E₁-E_{M-N}). Shift register 306 may be configured to shift the values of input signals received from DAC 302 through elements Eᵢ of shift register 306 according to a received clock signal. In the present example, elements Eᵢ may comprise D flip-flops. For example, upon receiving a clock signal, each element Eᵢ may store an input signal and output a signal that may have been stored upon receiving the previous clock signal. Accordingly, each element Eᵢ may store and output previous values of the output signal such that each element Eᵢ may be associated with an order number of sFIR filter 304. The input of shift register 306 and the output of each element Eᵢ of shift register 306 may be coupled to a resistor Resistors Rᵢ may also be coupled to the output of filter 304. For example, resistor R₀ may be coupled to the input of shift register 306 at one end and the output of filter 304 at the other end, resistor R₁ may be coupled to the output of element E₁ at one end and the output of filter 304 at its other end, etc.

Each resistor Rᵢ, and its associated element Eᵢ, of filter 304 may be associated with a tap of filter 304 that may affect the analog corner frequency of filter 304. The number of taps of filter 304 and the resistors associated with the taps may affect the resistance associated with the analog corner frequency of filter 304. Therefore, by adding or subtracting taps of filter 304, the resistance associated with the analog corner frequency of filter 304 may be adjusted.

In the present example, filter 304 may also include “2×N” number of single element shift registers 308 (e.g., registers 308₁-308_{2N}) that may each include an element Eᵢ (e.g., elements E_{M-N+1}-E_{M+N}) configured to store and shift previous values of an input signal received from each register's previous input. Similar to the elements Eᵢ of shift register 306, each element Eᵢ of shift registers 308 may be associated with a resistor Rᵢ. Unlike the elements Eᵢ of shift register 306, the output of elements Eᵢ of each shift register 308 may be coupled to a switch 310 (e.g., switches 310₁-310_{2N}). Switches 310 may be configured to be opened or closed to couple or decouple the output of the element Eᵢ of the shift register 308 with its associated resistor Rᵢ. Thus, switches 310 may be configured to couple or decouple elements Eᵢ of registers 308 to the output of filter 304 to adjust the number of taps of filter 304, which may affect the resistance of filter 304 associated with the analog corner frequency of filter 304.

For example, switch 310₁ may be coupled between resistor R_{M-N+1} and the output of element E_{M-N+1} of register 308₁. Accordingly, when closed, switch 310₁ may couple the output of element E_{M-N+1} with resistor R_{M-N+1} such that a tap associated with resistor R_{M-N+1} may be added to filter 304 and the resistance of R_{M-N+1} may affect the analog corner frequency of filter 304. Similarly, when open, switch 310₁ may decouple the output of element E_{M-N+1} from resistor R_{M-N+1} such that the tap associated with resistor R_{M-N+1} and E_{M-N+1} may not be included in filter 304 and the resistance of resistor R_{M-N+1} may not affect the corner frequency of filter 304.

Switches 310 may comprise any suitable switch configured to open and close according to a received control signal. In the present example, switches 310 may be coupled to a controller (e.g., controller 211 of FIG. 2) and may receive the control signals from the controller. In some embodiments, switches 310 may comprise a tri-state buffer that may close upon receiving a “HIGH” control signal at a tri-state terminal and that may open upon receiving a “LOW” control signal at the tri-state terminal.

In the present example, the number of taps of filter 304 (and their associated elements Eᵢ and resistors Rᵢ) may be related to the desired corner frequency of filter 304 and the fabrication variations of filter 304. For example, in the present embodiment, it may be determined that filter 304 may substantially achieve the desired corner frequency if filter 304 has “M” number of taps and their associated elements Eᵢ and “resistors Rᵢ. However, in the present example, the fabrication process of filter 304 may have a variation of 10%. Therefore, in some instances of the present example, upon fabrication of filter 304, to achieve the desired corner frequency of filter 304, the number of taps of filter 304 may need to be adjusted by plus or minus 10% to compensate for the 10% fabrication tolerance.

In the present example, in order to substantially achieve the desired corner frequency of filter 304, filter 304 may be configured to adjust the number of taps of filter 304 by “N” such that the number of taps of filter 304 may be approximately equal to “M±N.” Therefore, in the present example, shift register 306 may include “M” minus “N” (“M−N”) elements Eᵢ, that may be coupled at their output to their associated resistors Rᵢ without a switch 310 coupled between the output of the elements Eᵢ and the resistors Rᵢ because “M−N” elements Eᵢ and their associated resistors Rᵢ may be used regardless of variations that may occur in the fabrication process.

Additionally, in the present example, filter 304 may include 2×N single element shift registers 308 that may each be associated with an element Eᵢ, Rᵢ and their associated taps. The output of each element Eᵢ of each shift register 308 may be coupled to or decoupled from its associated resistor Rᵢ by a switch 310 such that taps may be added to or subtracted from filter 304 by closing or opening, respectively, one or more switches 310. Therefore, depending on the variations that occur in the fabrication process, anywhere from zero to 2×N taps may be added to filter 304 to achieve the desired analog corner frequency of filter 304. The analog corner frequency of sFIR filter 304 may be measured upon fabricating filter 304 and the controller of the element associated with sFIR filter 304 (e.g., controller 211 of element 200 in FIG. 2) may be configured to enable and/or disable switches 310 accordingly.

For example, if the process variation is such that filter 304 may substantially have the desired corner frequency with “M−N” taps, switches 310₁ through 310_{2N} may be opened such that the outputs of shift registers 308₁ through 308_{2N} are not coupled to the output of filter. Accordingly, filter 304 may comprise “M−N” taps to achieve the desired corner frequency based at least partially on the resistances associated with the taps.

As another example, in other instances, the process variation may be such that “M+N” taps of filter 304 (and their associated resistances based on resistors Rᵢ) may achieve the desired analog corner frequency of filter 304. In such instances, every switch 310 may be closed such that each register 308 adds a tap to filter 304 to achieve “M+N” taps of sFIR filter 304 such that the corner frequency of filter 304 is substantially equal to the desired corner frequency.

Therefore, sFIR filter 304 may be configured to be tunable to account for potential variations in the actual analog corner frequency versus the desired analog corner frequency due to fabrication process variations. As such, the accuracy of signals generated by VCO module 310 may be improved to improve the performance of oscillator circuit 210. Additionally, the number of taps that may be added or subtracted from sFIR filter 304 (and their associated resistors Rᵢ, elements Eᵢ and switches 310) may at least be partially based on the fabrication process variations of the circuit. By basing the number of taps that may be added or subtracted in part, according to the fabrication process variations, the amount of chip space occupied by sFIR filter 304 may be reduced.

Modifications, additions and omissions may be made to FIG. 3 without departing from the scope of the present disclosure. For example, although the specific embodiment depicted includes some, but not all elements Eᵢ associated with switches 310 that may couple or decouple the elements Eᵢ with the output of filter 304 in other embodiments, every element Eᵢ may be associated with a switch 310 to provide a greater tunable range of filter 304. Also, although described as having a number of switches 310, elements Eᵢ and resistors Rᵢ based partially on the fabrication process variations of filter 304, any number of reasons may be used to vary the number of any one of these components. Additionally, although separate shift registers (e.g., register 306 and registers 308) are described and depicted as having a certain number of elements associated with them, it is understood that any suitable shift register with any suitable number of elements may be used. Further, although the present disclosure describes the use of tunable filter 304 in the context of a wireless communication element, tunable filter 304 may be used with any suitable circuit where a tunable sFIR filter may be desirable. Additionally, although certain components may be described and/or depicted as being “coupled” or “communicatively coupled” to each other, it is understood that intermediate components may be included between the “coupled” components.

Although the present disclosure has been described with several embodiments, various changes and modifications may be suggested to one skilled in the art. It is intended that the present disclosure encompass such changes and modifications as fall within the scope of the appended claims.

What is claimed is:

1. A tunable semi-digital finite impulse response (sFIR) filter comprising:
an input terminal;
an output terminal;
a plurality of shift register elements, each associated with a tap of the sFIR filter, the plurality of shift register elements comprising at least:
a first shift register element communicatively coupled to the input terminal at an input of the first shift register element; and
a second shift register element communicatively coupled to an output of the first shift register element at an input of the second shift register element;
a plurality of resistors, each associated with a tap of the sFIR filter and communicatively coupled between an output of an associated shift register element of the plurality of shift register elements and the output terminal of the sFIR filter; and
a plurality of switches, each communicatively coupled between the output of a shift register element and its associated resistor, the switches configured to open and close in response to a control signal in order to tune a corner frequency of the sFIR filter by adding or subtracting taps to the sFIR filter.

2. The sFIR filter of claim 1, the control signal based at least on noise associated with a control voltage received from a digital to analog converter (DAC) communicatively coupled to the input terminal of the sFIR filter, the sFIR filter configured to filter the control voltage according to the corner frequency and output the filtered control voltage at the output terminal of the sFIR filter, the output terminal communicatively coupled to a voltage controlled oscillator (VCO) module configured to receive the filtered control voltage and generate an oscillating signal based on the filtered control voltage.

3. The sFIR filter of claim 1, wherein:
the plurality of shift register elements includes one or more intermediate shift register elements, each intermediate shift register element communicatively coupled at its input to an output of another shift register element;
the plurality of resistors includes one or more intermediate resistors, each intermediate resistor communicatively coupled between the output of an associated shift register element and the output terminal of the sFIR filter; and
the plurality of switches includes one or more intermediate switches, each intermediate switch communicatively coupled between the output of an intermediate shift register element and its associated intermediate resistor, the intermediate switches configured to open and close in response to the control signal in order to tune the corner frequency of the sFIR filter.

4. The sFIR filter of claim 1, further comprising a capacitor.

5. The sFIR filter of claim 4, the corner frequency based at least on a capacitance of the capacitor and a resistance of resistors associated with switches that are closed.

6. The sFIR filter of claim 1, the switches each comprising a tri-state buffer.

7. The sFIR filter of claim 1, the plurality of switches comprising a number of switches determined based on a fabrication process variation of the sFIR filter.

8. The sFIR filter of claim 1, the plurality of resistors comprising a number of resistors determined based on a fabrication process variation of the sFIR filter.

9. The sFIR filter of claim 1, the plurality of shift register elements comprising a number of shift register elements determined based on the desired filter frequency and the fabrication process variation of the sFIR filter.

10. An oscillating circuit comprising:
a digital to analog converter (DAC) configured to generate a control voltage;
a voltage controlled oscillator (VCO) module configured to generate an oscillating signal based on the control voltage; and
a tunable semi-digital finite impulse response (sFIR) filter configured to filter the control voltage according to a corner frequency, the sFIR filter comprising:
an input terminal communicatively coupled to the DAC and configured to receive the control voltage;
an output terminal communicatively coupled to the VCO module and configured to communicate the filtered control voltage to the VCO module;
a plurality of shift register elements, each associated with a tap of the sFIR filter, the plurality of shift register elements comprising at least:
a first shift register element communicatively coupled to the input terminal at an input of the first shift register element; and
a second shift register element communicatively coupled to an output of the first shift register element at an input of the second shift register element;
a plurality of resistors, each associated with a tap of the sFIR filter and communicatively coupled between an output of an associated shift register element of the plurality of shift register elements and the output terminal of the sFIR filter; and
a plurality of switches, each communicatively coupled between the output of a shift register element and its associated resistor, the switches configured to open and close in response to a control signal in order to tune the corner frequency of the sFIR filter.

11. The oscillating circuit of claim 10, wherein:
the plurality of shift register elements includes one or more intermediate shift register elements, each intermediate shift register element communicatively coupled at its input to an output of another shift register element;
the plurality of resistors includes one or more intermediate resistors, each intermediate resistor communicatively coupled between the output of an associated shift register element and the output terminal of the sFIR filter; and
the plurality of switches includes one or more intermediate switches, each intermediate switch communicatively coupled between the output of an intermediate shift register element and its associated intermediate resistor, the intermediate switches configured to open and close in response to the control signal in order to tune the corner frequency of the sFIR filter.

12. The oscillating circuit of claim 10, the sFIR filter further comprising a capacitor.

13. The oscillating circuit of claim 12, the corner frequency based at least on a capacitance of the capacitor and a resistance of resistors associated with switches that are closed.

14. The oscillating circuit of claim 10, the switches each comprising a tri-state buffer.

15. The oscillating circuit of claim 10, the plurality of switches comprising a number of switches determined based on a fabrication process variation of the sFIR filter.

16. The oscillating circuit of claim 10, the plurality of resistors comprising a number of resistors determined based on a fabrication process variation of the sFIR filter.

17. The oscillating circuit of claim 10, the plurality of shift register elements comprising a number of shift register elements determined based on a fabrication process variation of the sFIR filter and the desired filter frequency.

18. A method for tuning a semi-digital finite impulse response (sFIR) filter comprising:
coupling a switch between an output of a shift register element associated with an input of the sFIR filter and a resistor coupled to an output of the sFIR filter, the shift register element and the resistor associated with a tap of the sFIR filter; and at least one of:
closing the switch according to a control signal to couple the resistor with the output of the shift register element such that a tap is added to the sFIR filter in order to tune a corner frequency of the sFIR filter; and
opening the switch according to the control signal to decouple the resistor from the output of the shift register element such that a tap is subtracted from the sFIR filter in order to tune the corner frequency of the sFIR filter.

19. The method of claim 18, the corner frequency based at least on noise associated with a control voltage received from a digital to analog converter (DAC) communicatively coupled to the input of the sFIR filter.

20. The method of claim 18, the corner frequency a function of at least a resistance of the resistor and a capacitance of a capacitor coupled to the output of the sFIR filter when the switch is closed.
